(19) United States
(12) Patent Application Publication
(10) Pub. No.: US 2026/0120738 A1
(43) Pub. Date: Apr. 30, 2026

(54) DUAL MODE INVERTER-BASED WRITE TERMINATION CIRCUIT, METHOD THEREOF, AND DEVICES HAVING THE SAME

(71) Applicant: UIF (University Industry Foundation), Yonsei University, Seoul (KR)

(72) Inventors: SEONG-OOK JUNG, Seoul (KR); DO YOON LIM, Seoul (KR); DONG HAN KO, Seoul (KR); WAN GYU LEE, Seoul (KR)

(21) Appl. No.: 19/368,790

(22) Filed: Oct. 24, 2025

(30) Foreign Application Priority Data
Oct. 30, 2024 (KR) 10-2024-0150321

(51) Int. Cl. G11C 11/16; H03K 3/037

(52) U.S. Cl. CPC G11C 11/1675; G11C 11/1673; G11C 11/1693; H03K 3/0377

(57) ABSTRACT

A memory device includes: a memory cell, a reference memory cell, and a dual mode inverter-based write termination circuit including a write driver for writing data to the memory cell, the dual mode inverter-based write termination circuit detecting the completion of writing data to the memory cell and terminating the operation of the write driver, and also sequentially receiving an output signal of the reference memory cell and an output signal of the memory cell through one input node to sense and amplify the data stored in the memory cell.

### CROSS-REFERENCE TO RELATED APPLICATIONS

This application claims priority under 35 U.S.C. § 119(a) to Korean Patent Application No. 10-2024-0150321, filed on Oct. 30, 2024, with the Korean Intellectual Property Office, the disclosure of which is incorporated herein in its entirety by reference.

### BACKGROUND

The present disclosure relates to a write termination circuit, and more specifically, to a dual mode inverter-based write termination circuit capable of controlling the operation of a write driver that writes data to a memory device and also performing the function of a sense amplifier that senses and amplifies data stored in the memory device, a method of operating the same, and devices including the dual mode inverter-based write termination circuit.

Spin-Transfer Torque Magnetic Random-Access Memory (STT-MRAM) is a nonvolatile memory device that utilizes magnetic spin. STT-MRAM is an improved version of MRAM, storing data by changing the direction of the magnetic spin. STT-MRAM has the advantages of low power consumption, fast read/write speed, and being non-volatile, which means data is retained even when power is turned off.

STT-MRAM can control the spin direction of electrons using spin current. STT-MRAM stores data by changing the direction of the magnetic layer using spin current.

The core of STT-MRAM is a magnetic tunnel junction structure, with an insulating layer placed between two magnetic layers. The tunneling resistance varies depending on the relative orientation of the two magnetic layers (e.g., parallel or antiparallel), enabling the representation of data states of 0 or 1.

STT-MRAM consumes a significant amount of current during write operations. To reduce this current consumption, a write termination circuit is used. The addition of a write termination circuit to STT-MRAM increases the space occupied by the write termination circuit in the memory cell array containing STT-MRAM cells, i.e., the layout area. This, in turn, negatively impacts the integration density of the STT-MRAM.

### SUMMARY

An object of the present disclosure is to provide a dual mode inverter-based write termination circuit that can reduce the layout area, be used as a write termination circuit that can control the operation of a write driver during data write operation, and can also be used as a sense amplifier during data read operation, a method of operating the same, and devices including the dual mode inverter-based write termination circuit.

A dual mode inverter-based write termination circuit according to embodiments of the present disclosure includes: a first inverter including a first input node receiving a first input signal and a first output node outputting a first output signal; a second inverter including a second input node and a second output node; a second switch connected between the first output node and the second input node; a second pull-up circuit for pulling up the second input node to a first voltage in response to a first control signal; a second pull-down circuit for pulling down the second input node to a second voltage in response to a second control signal; and a voltage maintenance circuit for maintaining a second output signal of the second output node.

The dual mode inverter-based write termination circuit may further include: an exclusive OR circuit that performs an exclusive OR operation on the second output signal and data; a NAND circuit that performs a NAND operation on the output signal of the exclusive OR circuit and an inverted read enable signal; a D flip-flop including a clock terminal that receives the output signal of the NAND circuit, an input terminal that receives the first voltage, and an output terminal that outputs a write termination signal; and a write driver that performs either a write operation or a write termination operation on a Spin-Transfer Torque Magnetic Random-Access Memory in response to the write termination signal.

An operating method of a dual mode inverter-based write termination circuit according to embodiments of the present disclosure includes the steps of: determining whether the dual mode inverter-based write termination circuit will be used as a write termination control circuit or a sense amplifier in response to an operation mode control signal; arranging switches included in the dual mode inverter-based write termination circuit into a first switch array to use the dual mode inverter-based write termination circuit as the write termination control circuit based on the result of the determination; and arranging the switches into a second switch array to use the dual mode inverter-based write termination circuit as the sense amplifier based on the result of the determination.

A memory device according to embodiments of the present disclosure includes: a memory cell, a reference memory cell, and a dual mode inverter-based write termination circuit including a write driver for writing data to the memory cell, the dual mode inverter-based write termination circuit detecting the completion of writing data to the memory cell and terminating the operation of the write driver, and also sequentially receiving an output signal of the reference memory cell and an output signal of the memory cell through one first input node to sense and amplify the data stored in the memory cell.

A memory system according to embodiments of the present disclosure includes a processor that outputs data and a memory device that receives the data, the memory device including: a memory cell, a reference memory cell, and a dual mode inverter-based write termination circuit including a write driver for writing data to the memory cell, the dual mode inverter-based write termination circuit detecting the completion of writing data to the memory cell and terminating the operation of the write driver, and also sequentially receiving an output signal of the reference memory cell and an output signal of the memory cell through one first input node to sense and amplify the data stored in the memory cell.

A dual purpose circuit according to an embodiment of the present disclosure, i.e., a dual mode inverter-based write termination circuit, can be used as a write termination circuit that can control the operation of a write driver during data write operation and can also be used as a sense amplifier during data read operation, thereby having the effect of reducing area overhead.

A dual mode inverter-based write termination circuit according to an embodiment of the present disclosure includes a sense amplifier including stacked transistors, and has the effect of increasing a sensing margin by receiving and sensing an input signal using both an NMOS transistor and a PMOS transistor included in the sense amplifier.

The sense amplifier included in the dual mode inverter-based write termination circuit can reduce static current consumption by utilizing stacked transistors, thereby reducing power overhead, i.e., additional power consumption.

Since the sense amplifier has a single-ended sense amplifier structure, it can perform an amplification operation using transistors having small sizes implemented therein, thereby reducing not only area overhead but also power overhead.

Since the sense amplifier can be used as a pre-amplifier, it has the effect of reducing the offset of the sense amplifier.

In addition, the Schmitt trigger included in the dual mode inverter-based write termination circuit has the effect of increasing noise tolerance by having a structure that does not float the node between the sense amplifier and the inverter included in the Schmitt trigger.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram of a memory device including a dual mode inverter-based write termination circuit according to an embodiment of the present disclosure.

FIG. 2 is a circuit diagram of a dual purpose circuit of a write termination control circuit and a sense amplifier included in the dual mode inverter-based write termination circuit illustrated in FIG. 1.

FIG. 3 is a circuit diagram of the dual purpose circuit of the write termination control circuit and sense amplifier of FIG. 2 when used in write termination mode.

FIG. 4 is a circuit diagram of the dual purpose circuit of the write termination control circuit and sense amplifier of FIG. 2 when used in sense amplifier mode.

FIG. 5 is a circuit diagram of each of the switch circuit, memory cell, and reference memory cell of FIG. 1.

FIG. 6 is a block diagram of the control signal generation circuit of FIG. 1.

FIG. 7 is a timing diagram for explaining a first data write operation and a write termination operation performed by the dual mode inverter-based write termination circuit of FIG. 1.

FIG. 8 is a timing diagram for explaining a second data write operation and a write termination operation performed by the dual mode inverter-based write termination circuit of FIG. 1.

FIG. 9 is a timing diagram for explaining the sense amplifier mode performed by the dual mode inverter-based write termination circuit of FIG. 1.

FIG. 10 is a circuit diagram of each of a write termination control circuit and a sense amplifier combined circuit, a switch circuit, a memory cell, and a reference memory cell for explaining the first phase of the sense amplifier mode.

FIG. 11 is a circuit diagram of each of a write termination control circuit and a sense amplifier combined circuit, a switch circuit, a memory cell, and a reference memory cell for explaining the second phase of the sense amplifier mode.

FIG. 12 is a circuit diagram of each of a write termination control circuit and a sense amplifier combined circuit, a switch circuit, a memory cell, and a reference memory cell for explaining the third phase of the sense amplifier mode.

FIG. 13 is a flowchart for explaining the operation method of the memory device of FIG. 1.

FIG. 14 is a block diagram of a memory system including the memory device of FIG. 1.

### DETAILED DESCRIPTION OF THE INVENTION

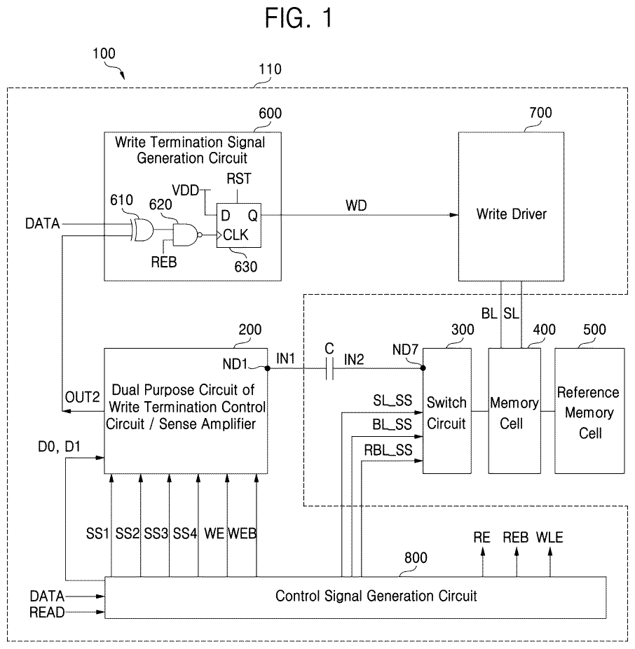

FIG. 1 is a block diagram of a memory device including a dual mode inverter-based write termination circuit according to an embodiment of the present disclosure.

Referring to FIG. 1, a semiconductor device, for example, a memory device 100, includes a dual mode inverter-based write termination (DMI-WT) circuit 110, a switch circuit 300, a memory cell 400, and a reference memory cell 500.

The memory device 100 may be an integrated circuit (IC), a system on chip (SoC), or a Spin-Transfer Torque Magnetic Random-Access Memory (STT-MRAM) device.

The DMI-WT circuit 110 is a dual-purpose circuit that may perform both the function of a write termination control circuit that detects whether a data write operation for the memory cell 400 has been completed during a data write operation and generates a write termination signal (WD) that may terminate (or disable) the operation of a write driver 700 based on the detection result, and the function of a sense amplifier that reads and amplifies data stored in the memory cell 400 and outputs an amplified second output signal (OUT2) during a data read operation.

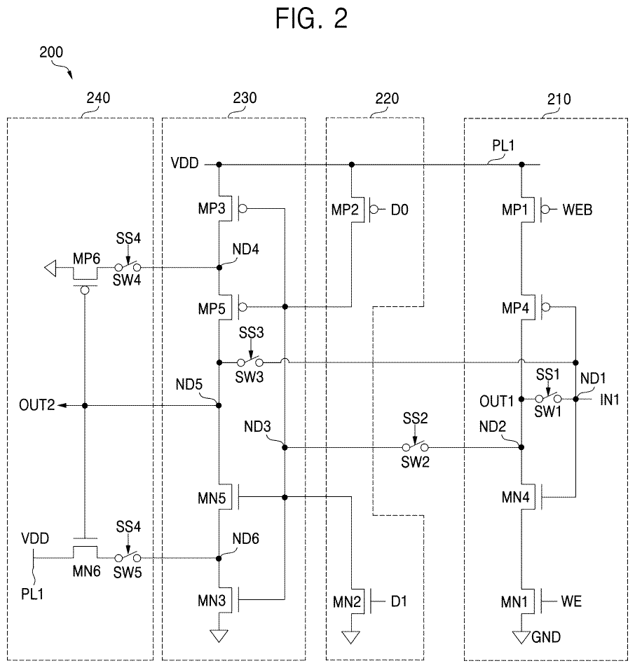

FIG. 2 is a circuit diagram of a dual purpose circuit of a write termination control circuit and a sense amplifier included in the dual mode inverter-based write termination circuit illustrated in FIG. 1.

Referring to FIGS. 1 and 2, the write termination control circuit and sense amplifier combined circuit 200 for controlling the operation of a write termination signal generation circuit 600 includes a first inverter 210 including a first input node ND1 receiving a first input signal IN1, a second switch SW2, a voltage setting circuit 220, a second inverter 230, and a voltage maintenance circuit 240. The voltage setting circuit 220, the second inverter 230, and the voltage maintenance circuit 240 may form a Schmitt trigger.

The first inverter 210 may be connected between the first voltage transmission line PL1 and the ground GND, and may receive and invert the first input signal IN1 of the first input node ND1 to generate a first output signal OUT1 and output it through the first output node ND2.

The first inverter 210 includes a first group of PMOS transistors MP1 and MP4 stacked to reduce power consumption and connected between a first voltage transmission line PL1 and a first output node ND2, a first group of NMOS transistors MN1 and MN4 stacked to reduce power consumption and connected between the first output node ND2 and ground GND, and a first switch SW1 connected between the first input node ND1 and the first output node ND2.

Although, for convenience of explanation, the first inverter 210 is illustrated as including the first switch SW1, the first switch SW1 may be placed outside the first inverter 210.

The stacked first PMOS transistors MP1 and MP4 perform the function of a first pull-up circuit that pulls up the first output signal OUT1 of the first output node ND2 to the level of the first voltage VDD, and the stacked first NMOS transistors MN1 and MN4 perform the function of a first pull-down circuit that pulls down the first output signal OUT1 of the first output node ND2 to the level of the second voltage.

The level of the first voltage VDD is higher than the level of the second voltage, and for convenience of explanation, the first voltage VDD is referred to as the operating voltage VDD and the second voltage is referred to as the ground voltage GND.

The inverted write enable signal WEB is input to the gate of the first PMOS transistor MP1, the write enable signal WE is input to the gate of the first NMOS transistor MN1, and the gate of the fourth PMOS transistor MP4 and the gate of the fourth NMOS transistor MN4 are connected to the first input node ND1.

The second switch SW2 is connected (or is directly connected) between the first output node ND2 and the second input node ND3.

The voltage setting circuit 220 sets the voltage of the second input terminal ND3 to the operating voltage VDD or ground voltage (or ground level) GND in the first phase of the write termination mode, i.e., the offset cancellation phase.

The voltage setting circuit 220 includes a second pull-up circuit MP2 and a second pull-down circuit MN2. The second pull-up circuit MP2 includes a second PMOS transistor MP2, and the second pull-down circuit MN2 includes a second NMOS transistor MN2.

The second pull-up circuit MP2 pulls up the second input terminal ND3 to the operating voltage VDD in response to the first control signal DO having the first level, and the second pull-down circuit MN2 pulls down the second input terminal ND3 to the ground voltage in response to the second control signal D1 having the second level.

Here, the first level is a low level that may turn on the PMOS transistor, and the second level is a high level that may turn on the NMOS transistor. Therefore, the PMOS transistor is turned off in response to a signal having the second level, and the NMOS transistor is turned off in response to a signal having the first level.

The second inverter 230 includes a third pull-up circuit, a third pull-down circuit, and a third switch SW3. Although, for convenience of explanation, the second inverter 230 is illustrated as including the third switch SW3, the third switch SW3 may be placed externally to the second inverter 230.

The third pull-up circuit includes a second group of PMOS transistors MP3 and MP5 connected in series between a first voltage transmission line PL1 and a second output node ND5. The gate of each PMOS transistor MP3 and MP5 is connected to a second input terminal ND3. In some embodiments, the second group of PMOS transistors MP3 and MP5 may be stacked transistors.

The third pull-down circuit includes a second group of NMOS transistors NM3 and MN5 connected in series between a second output node ND5 and ground GND. The gates of each NMOS transistor MN3 and MN5 are connected to a second input terminal ND3. In some embodiments, the second group of NMOS transistors NM3 and MN5 may be stacked transistors.

The third switch SW3 is connected (or is directly connected) between the first input node ND1 and the second output node ND5.

In the first phase of the write termination mode, i.e., the offset removal phase, the voltage maintenance circuit 240 performs the function of maintaining the second output signal OUT2 of the second output node ND5 at the operating voltage VDD or ground voltage.

The voltage maintenance circuit 240 includes a sixth PMOS transistor MP6, a fourth switch SW4, a sixth NMOS transistor MN6, and a fifth switch SW5.

The fourth switch SW4 and the sixth PMOS transistor MP6 are connected in series between the fourth node ND4 (i.e., the first common node) and ground GND, and the fifth switch SW5 and the sixth NMOS transistor MN6 are connected in series between the first voltage transmission line PL1 and the sixth node ND6 (i.e., the second common node).

The gate of the sixth PMOS transistor MP6 and the gate of the sixth NMOS transistor MN6 are connected to the second output node ND5 that outputs the second output signal OUT2.

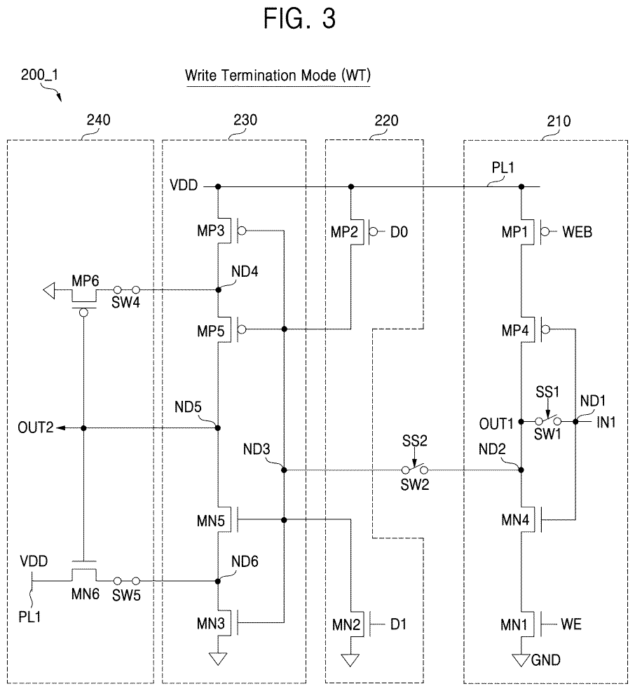

FIG. 3 is a circuit diagram of the dual purpose circuit of the write termination control circuit and sense amplifier of FIG. 2 when used in write termination mode.

Referring to FIGS. 2 and 3, in the write termination mode WT, the switches have a first switch array 200_1 in which the third switch SW3 is always kept in an off state, the fourth switch SW4 and the fifth switch SW5 are always kept in an on state, and each switch SW1 and SW2 is turned on or off according to each switch signal SS1 and SS2.

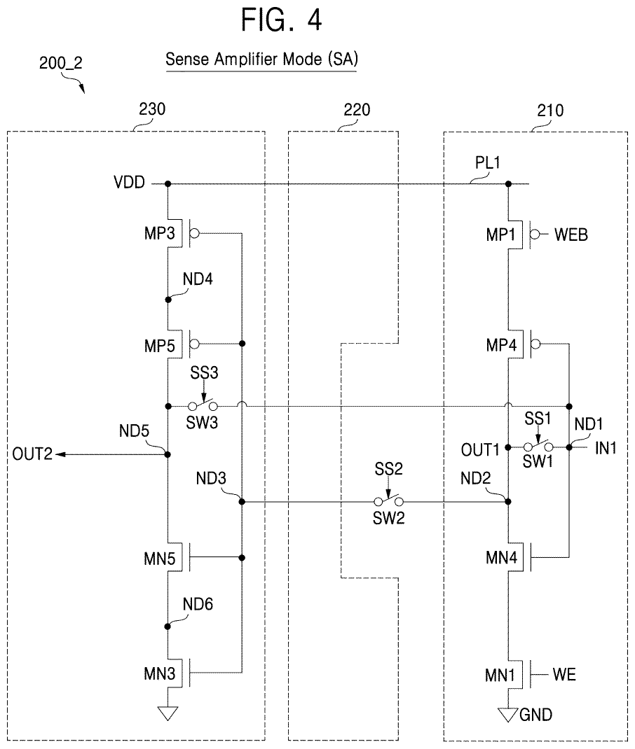

FIG. 4 is a circuit diagram of the dual purpose circuit of the write termination control circuit and sense amplifier of FIG. 2 when used in sense amplifier mode.

Referring to FIGS. 2 and 4, in the sense amplifier mode SA, the switches have a second switch array 200_2 in which the fourth switch SW4 and the fifth switch SW5 are always kept in an off state, and each switch SW1 to SW3 is turned on or off according to each switch signal SS1 to SS3.

Referring to FIGS. 2 to 4, each of the plurality of switches SW1 to SW5 is aligned in a first switch array 200_1 in the write termination mode WT and in a second switch array 200_2 in the sense amplifier mode SA. Here, alignment means that each switch SW1 to SW5 has an on state or an off state.

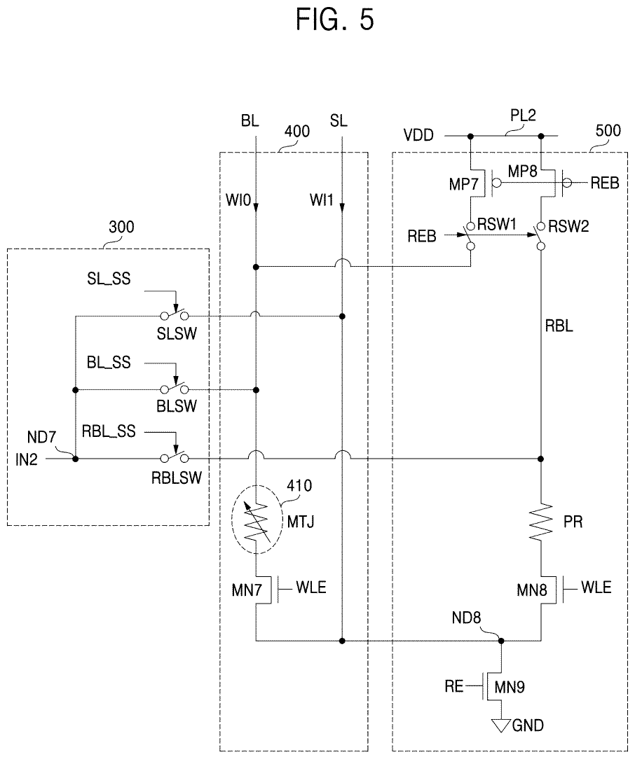

FIG. 5 is a circuit diagram of each of the switch circuit, memory cell, and reference memory cell of FIG. 1. Referring to FIG. 1 and FIG. 5, the switch circuit 300 includes a source line switch SLSW, a bit line switch BLSW, and a reference bit line switch RBLSW.

The source line switch SLSW is connected between a source line SL and a seventh node ND, the bit line switch BLSW is connected between a bit line BL and the seventh node ND, and the reference bit line switch RBLSW is connected between a reference bit line RBL and the seventh node ND.

The memory cell 400 implemented as STT-MRAM includes a cell transistor MN7 and a magnetic tunnel junction (MTJ) 410.

The reference memory cell 500 includes a seventh PMOS transistor MP7 and a first reference cell switch RSW1 connected in series between a second voltage transmission line PL2 (for example, PL1 and PL2 may be the same voltage transmission line or may be connected to each other) transmitting an operating voltage VDD and a bit line BL, an eighth PMOS transistor MP8 and a second reference cell switch RSW2 connected in series between the second voltage transmission line PL2 and the reference bit line RBL, a resistor PR and an eighth NMOS transistor MN8 connected in series between the reference bit line RBL and an eighth node ND8, and a ninth NMOS transistor MN9 connected between the eighth node ND8 and ground GND.

The word line enable signal WLE is input to the gate of each of the NMOS transistors MN7 and MN8, the inverted read enable signal REB is input to the gate of each PMOS transistor MP7 and MP8 and each switch RSW1 and RSW2, and the read enable signal RE is input to the gate of the ninth NMOS transistor MN9. The phase difference between the read enable signal RE and the inverted read enable signal REB is 180 degrees.

It is assumed that each switch SW1 to SW5, SLSW, BLSW, and RBLSW described herein is an NMOS transistor that is turned on in response to a switch signal SS1 to SS4, SL_SS, BL_SS, and RBL_SS having a second level, and each switch RSW1 and RSW2 is a PMOS transistor that is turned on in response to an inverted read enable signal REB having a first level.

For example, the first type MOS transistor is one of a PMOS transistor and an NMOS transistor, and the second type MOS transistor is the other one of the PMOS transistor and the NMOS transistor.

Referring back to FIG. 1, the write termination signal generation circuit 600 includes an exclusive OR circuit 610, a NAND circuit 620, and a D flip-flop 630. For example, the D flip-flop 630 may be a rising edge triggered flip-flop.

The exclusive OR circuit 610 performs an exclusive OR operation on the second output signal OUT2 and data DATA, and the NAND circuit 620 performs a NAND operation on the output signal of the exclusive OR circuit 610 and the inverted read enable signal REB.

The D flip-flop 630 includes a clock terminal CLK for receiving an output signal of the NAND circuit 620, an input terminal D for receiving a first voltage VDD, and an output terminal Q for outputting a write termination signal WD.

According to the reset signal RST, the D flip-flop 630 outputs a write termination signal WD having a first level (e.g., data ‘0’ or low level) to the write driver 700, so that the write driver 700 is enabled to supply a first write current WI0 to the bit line BL to write data ‘0’ to the memory cell 400, or supply a second write current WI2 to the source line SL to write data ‘1’ to the memory cell 400.

However, when the second output signal OUT2 transitions from the second level to the first level when data DATA is at the first level and the inverted read enable signal REB is at the second level (e.g., data ‘1’ or high level), the output signal of the exclusive OR circuit 610 transitions from the second level to the first level.

Accordingly, as the output signal of the NAND circuit 320 transitions from the first level to the second level, the D flip-flop 630 outputs a write termination signal WD having the second level, and the write driver 700 is disabled in response to the write termination signal

WD having the second level. As the write driver 700 is disabled (i.e., the write operation is terminated), the first write current WI0 supplied to the bit line BL or the second write current WI2 supplied to the source line SL becomes zero.

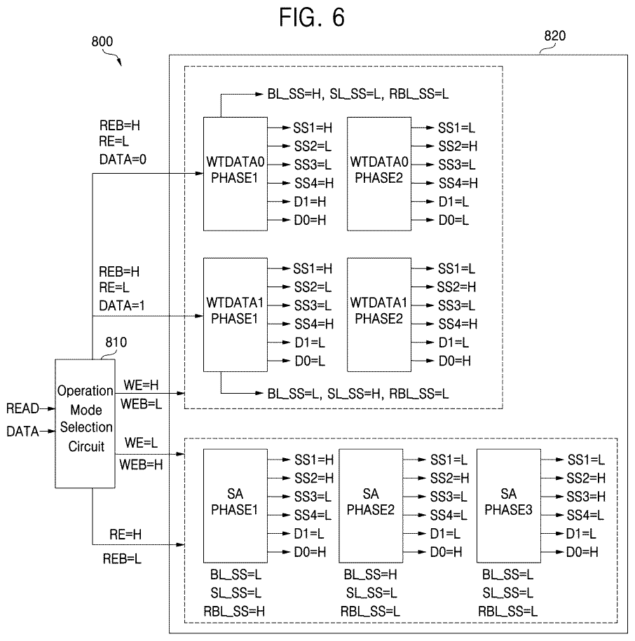

FIG. 6 is a block diagram of the control signal generation circuit of FIG. 1.

Referring to FIGS. 1 and 6, the control signal generation circuit 800 includes an operation mode selection (or control) circuit 810 and a switch control signal generation circuit 820.

The operation mode selection circuit 810 may receive an operation mode control signal READ and data DATA, and control the operation mode and phase of the control circuit 200 in response to these READ and DATA.

For example, when the operation mode control signal READ is at the first level, the write termination mode WT is performed, and when the operation mode control signal READ is at the second level, the sense amplifier mode SA is performed.

The operation modes include write termination mode WT and sense amplifier mode SA.

In the write termination mode WT, the operation mode selection circuit 810 generates a read enable signal RE having a first level L, an inverted read enable signal REB having a second level H, a write enable signal WE having a second level H, and an inverted write enable signal WEB having a first level L.

However, in the sense amplifier mode SA, the operation mode selection circuit 810 generates a read enable signal RE having a second level (H), an inverted read enable signal REB having a first level L, a write enable signal WE having a first level L, and an inverted write enable signal WEB having a second level H.

When the operation mode control signal READ is at the first level L and data DATA is ‘0’, the DMI-WT circuit 200 generates control signals SS1, SS2, SS3, SS4, DO, D1, BL_SS, SL_SS, and RBL_SS for sequentially performing the first phase WTDATA0_PHASE1 and the second phase WTDATA0_PHASE2 of the first write termination mode WT to write data DATA ‘0’ to the memory cell 400.

However, when the operation mode control signal READ is at the first level L and data DATA is ‘1’, the DMI-WT circuit 200 generates control signals SS1, SS2, SS3, SS4, DO, D1, BL_SS, SL_SS, and RBL_SS for sequentially performing the first phase WTDATA1_PHASE1 and the second phase WTDATA1_PHASE2 of the second write termination mode WT to write data DATA ‘1’ to the memory cell 400.

When the operation mode control signal READ is at the second level H, the operation mode selection circuit 810 selects the sense amplifier mode SA.

When the operation mode control signal READ is at the second level H, regardless of data DATA, the DMI-WT circuit 200 generates control signals SS1, SS2, SS3, SS4, DO, D1, BL_SS, SL_SS, and RBL_SS for sequentially performing the first phase SA_PHASE1, the second phase SA_PHASE2, and the third phase SA_PHASE3 of the sense amplifier to sense and amplify data stored in the memory cell 400.

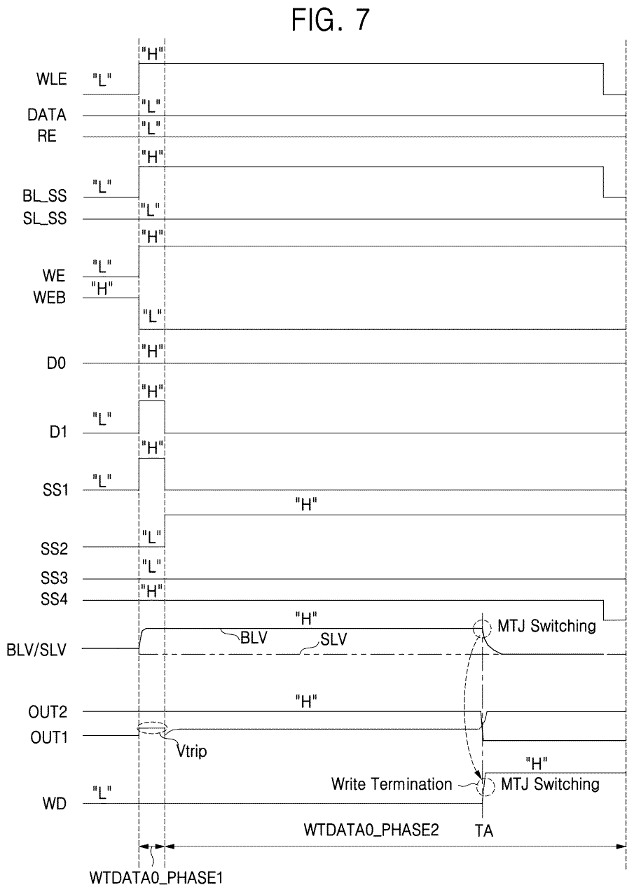

FIG. 7 is a timing diagram for explaining a first data write operation and a write termination operation performed by the dual mode inverter-based write termination circuit of FIG. 1.

The first phase WTDATA0_PHASE1 and the second phase WTDATA0_PHASE2 of the first write termination mode WT performed sequentially are described with reference to FIGS. 1 to 7.

The first phase WTDATA0_PHASE1 of the first write termination mode WT is an offset removal phase.

In the first phase WTDATA0_PHASE1 of the first write termination mode WT, the first switch SW1 is turned on in response to the first switch signal SS1 having the second level H, the fourth switch SW4 and the fifth switch SW5 are each turned on in response to the fourth switch signal SS4 having the second level H, the second switch SW2 is maintained in the off state in response to the second switch signal SS2 having the first level L, and the third switch SW3 is maintained in the off state in response to the third switch signal SS3 having the first level L.

When the first switch SW1 is turned on, the first input node ND1 and the first output node ND2 of the first inverter 210 are connected to each other, so that the first input signal IN1 and the first output signal OUT1 become the same, and the offset of the first inverter 210 can be removed.

Here, the first inverter 210 and the second inverter 230 are separated from each other by switches SW2 and SW3 that have an off state.

When the first control signal DO and the second control signal D1 are each at the second level H, the second PMOS transistor MP2 is turned off and the second NMOS transistor MN2 is turned on, so that the voltage of the second input node ND3 is pulled down to the ground voltage GND.

As the voltage of the second input node ND3 is pulled down to the ground voltage GND, each PMOS transistor MP3 and MP5 turns on and each NMOS transistor MN3 and MN5 turns off.

Accordingly, the second output signal OUT2 of the second output terminal ND5 is pulled up to the first voltage, i.e., the operating voltage VDD, and the sixth PMOS transistor MP6 is turned off in response to the operating voltage VDD, so that the voltage of the fourth node ND4 maintains the operating voltage VDD, and the fifth PMOS transistor MP5, which maintains the turn-on state, supplies the operating voltage VDD to the second output node ND5.

Additionally, the sixth NMOS transistor MN6, which is turned on in response to the operating voltage VDD, supplies the operating voltage VDD to the sixth node ND6 through the fifth switch SW5, so the fifth NMOS transistor MN5 remains in the off state.

The exclusive OR circuit 610 generates an output signal having a second level H based on data ‘0’ and the second output signal OUT2 having a second level H, and the NAND circuit 620 generates a signal having a first level L according to the output signal of the exclusive OR circuit 610 having a second level H and an inverted read enable signal REB having a second level H, and outputs the signal to the clock terminal CLK of the D flip-flop 630, so that the D flip-flop 630 generates a write termination signal WD having a first level L and outputs it to the write driver 700.

As the word line enable signal WLE having the second level H is supplied to the gate of each of the NMOS transistors MN7 and MN8, the NMOS transistors MN7 and MN8 are turned on.

As the read enable signal RE having the first level L is supplied to the gate of the NMOS transistor MN9, the NMOS transistor MN9 is maintained in an off state, and as the inverted read enable signal REB having the second level H is supplied to the PMOS transistors MP7 and MP8 and the switches RSW1 and RSW2, each of the PMOS transistors MP7 and MP8 and the switches RSW1 and RSW2 is maintained in an off state.

The write driver 700 supplies a first write current WI0 (for example, a first write pulse current) to the bit line BL in response to a write termination signal WD having a first level L, so that the voltage BLV of the bit line BL increases and the voltage SLV of the source line SL decreases.

The voltage BLV of the bit line BL is supplied to the first output node ND2 through the turned-on bit line switch BLSW, the capacitor C, and the turned-on first switch SW1, so that the first output signal OUT1 rises by the trip voltage Vtrip.

A write enable signal WE having a second level H is supplied to the first NMOS transistor MN1, and an inverted write enable signal WEB having a first level L is supplied to the first PMOS transistor MP1, and each MOS transistor MP1 and MN1 is turned on.

The second phase WTDATA0_PHASE2 of the first write termination mode WT is the write termination phase.

In the second phase WTDATA0_PHASE2 of the first write termination mode WT, the first switch SW1 is turned off in response to the first switch signal SS1 having the first level L, and the third switch SW3 is maintained in the off state in response to the third switch signal SS3 having the first level L.

The second switch SW2, the fourth switch SW4, and the fifth switch SW5 are each turned on in response to the second switch signal SS2 and the fourth switch signal SS4 having the second level H, respectively.

The first output node ND2 of the first inverter 210 and the second input node ND3 of the second inverter 230 are connected to each other by a second switch SW2 that is in an on state.

When the second control signal D1 transitions from the second level H to the first level L while the first control signal DO maintains the second level H, each MOS transistor MP2 and MN2 is turned off.

When MTJ switching occurs in the MTJ 410 at the first time point TA according to the first write current WI0 supplied to the bit line BL by the write driver 700, the resistance value of the MTJ 410 decreases and accordingly, the voltage BLV of the bit line BL gradually decreases.

The voltage BLV of the bit line BL that is gradually decreasing is supplied to the seventh node ND7 through the turned-on bit line switch BLSW, and as the second input signal IN2 of the seventh node ND7 decreases, the first input signal IN1 of the first input node ND1 also gradually decreases according to the coupling operation of the capacitor C.

As the first input signal IN1 of the first input node ND1 gradually decreases, the fourth PMOS transistor MP4 is turned on and the fourth NMOS transistor MN4 is turned off, so the first output signal OUT1 of the first output node ND2 of the first inverter 210 increases to the operating voltage VDD.

The first output signal OUT1, i.e., the operating voltage VDD, is transmitted to the second input node ND3 of the second inverter 220 through the turned-on second switch SW2.

As the voltage of the second input node ND3 increases to the operating voltage VDD, the PMOS transistors MP3 and MP5 are turned off and the NMOS transistors MN3 and MN5 are turned on.

Therefore, the second output signal OUT2 of the second output node ND5 is pulled down from the operating voltage VDD to the ground voltage GND.

The exclusive OR circuit 610 generates an output signal having a first level L according to the second output signal OUT2 having data ‘0’ and a first level L, and the NAND circuit 620 generates a signal having a second level H according to the output signal of the exclusive OR circuit 610 having the first level L and the inverted read enable signal REB having the second level H, and outputs the signal to the clock terminal CLK of the D flip-flop 630. Therefore, the D flip-flop 630 generates a write termination signal WD having a second level H in response to the NAND circuit 620 transitioning to the second level H, and outputs the signal to the write driver 700.

The write driver 700 terminates the operation of writing data ‘0’ to the memory cell 400 in response to the write termination signal WD having the second level H, so that the first write current WI0 supplied to the bit line BL is cut off. Accordingly, the voltage BLV of the bit line BL drops to the ground voltage GND.

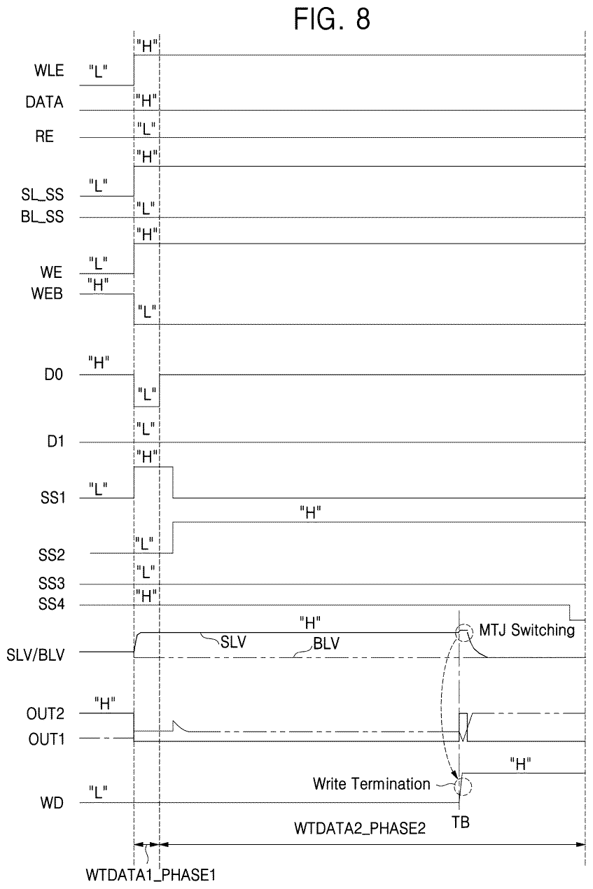

As the second input signal IN2 having a ground voltage GND is supplied to the first input node ND1 of the first inverter 210 through the turned-on bit line switch BLSW and the capacitor C, the first inverter 210 outputs a first output signal OUT1 having a second level H, and the second inverter 220 outputs a second output signal OUT2 having a first level L. FIG. 8 is a timing diagram for explaining a second data write operation and a write termination operation performed by the dual mode inverter-based write termination circuit of FIG. 1.

Referring to FIGS. 1, 2, 3, 7, and 8, the DMI-WT circuit 110 senses a change in the voltage BLV of the bit line BL in the second phase WTDATA0_PHASE2 of the first write termination mode WT and generates a termination signal WD having a second level H, and senses a change in the voltage SLV of the source line SL in the second phase WTDATA2_PHASE2 of the second write termination mode WT and generates a termination signal WD having a second level H.

The first phase WTDATA1_PHASE1 and the second phase WTDATA1_PHASE2 of the second write termination mode WT performed sequentially are described with reference to FIGS. 1 to 6 and FIG. 8.

The first phase WTDATA1_PHASE1 of the second write termination mode WT is an offset removal phase.

In the first phase WTDATA1_PHASE1 of the second write termination mode WT, the first switch SW1 is turned on in response to the first switch signal SS1 having the second level H, the fourth switch SW4 and the fifth switch SW5 are each turned on in response to the fourth switch signal SS4 having the second level H, the second switch SW2 is maintained in the off state in response to the second switch signal SS2 having the first level L, the third switch SW3 is maintained in the off state in response to the third switch signal SS3 having the first level L, and the source line switch SLSW is turned on in response to the source line switch signal SL_SS.

When the first switch SW1 is turned on, the first input node ND1 and the first output node ND2 of the first inverter 210 are connected to each other, so that the first input signal IN1 and the first output signal OUT1 become the same, and the offset of the first inverter 210 can be removed.

Here, the first inverter 210 and the second inverter 230 are separated from each other by switches SW2 and SW3 that have an off state.

When the first control signal DO and the second control signal D1 are each at the first level L, the second PMOS transistor MP2 is turned on and the second NMOS transistor MN2 is turned off, so that the voltage of the second input node ND3 is pulled up to the operating voltage VDD.

As the voltage of the second input node ND3 is pulled up to the operating voltage VDD, each PMOS transistor MP3 and MP5 turns off and each NMOS transistor MN3 and MN5 turns on.

Accordingly, the second output signal OUT2 of the second output terminal ND5 is pulled down to the second voltage, i.e., the ground voltage GND, and the sixth PMOS transistor MP6 is turned on in response to the ground voltage GND, so that the voltage of the fourth node ND4 is maintained at the ground voltage GND.

However, the fifth NMOS transistor MN6 remains in the off state.

The exclusive OR circuit 610 generates an output signal having a second level H according to the second output signal OUT2 having data ‘1’ and a first level L, and the NAND circuit 620 generates a signal having a first level L according to the output signal of the exclusive OR circuit 610 having a second level H and an inverted read enable signal REB having a second level H, and outputs the signal to the clock terminal CLK of the D flip-flop 630, so that the D flip-flop 630 generates a write termination signal WD having a first level L and outputs it to the write driver 700.

As the word line enable signal WLE having the second level (H) is supplied to the gate of each of the NMOS transistors MN7 and MN8, the NMOS transistors MN7 and MN8 are turned on.

As the read enable signal RE having the first level L is supplied to the gate of the NMOS transistor MN9, the NMOS transistor MN9 is maintained in an off state, and as the inverted read enable signal REB having the second level His supplied to the PMOS transistors

MP7 and MP8 and the switches RSW1 and RSW2, each of the PMOS transistors MP7 and MP8 and the switches RSW1 and RSW2 is maintained in an off state.

The write driver 700 supplies a second write current WI1 (for example, a second write pulse current) to the source line SL in response to a write termination signal WD having a first level L, so that the voltage SLV of the source line SL increases and the voltage BLV of the bit line BL decreases.

The voltage SLV of the source line SL is supplied to the first output node ND2 through the turned-on source line switch SLSW, the capacitor C, and the turned-on first switch SW1, so that the first output signal OUT1 rises by the trip voltage Vtrip.

A write enable signal WE having a second level H is supplied to the first NMOS transistor MN1, and an inverted write enable signal WEB having a first level L is supplied to the first PMOS transistor MP1, and each MOS transistor MP1 and MN1 is turned on.

The second phase WTDATA1_PHASE2 of the second write termination mode WT is the write termination phase.

In the second phase WTDATA1_PHASE2 of the second write termination mode WT, the first switch SW1 is turned off in response to the first switch signal SS1 having the first level L, and the third switch SW3 is maintained in the off state in response to the third switch signal SS3 having the first level L.

The second switch SW2, the fourth switch SW4, and the fifth switch SW5 are each turned on in response to the second switch signal SS2 and the fourth switch signal SS4 having the second level H, respectively.

The first output node ND2 of the first inverter 210 and the second input node ND3 of the second inverter 230 are connected to each other by a second switch SW2 that is in an on state.

When the second control signal D1 transitions from the second level H to the first level L while the first control signal DO maintains the second level H, each MOS transistor MP2 and MN2 is turned off.

When MTJ switching occurs in the MTJ 410 at the second time point TB according to the second write current WI1 supplied to the source line SL by the write driver 700, the resistance value of the MTJ 410 increases and accordingly, the voltage SLV of the source line SL gradually increases.

The voltage SBLV of the source line SL that is gradually increasing is supplied to the seventh node ND7 through the turned-on source line switch SLSW, and as the second input signal IN2 of the seventh node ND7 increases, the first input signal IN1 of the first input node ND1 also gradually increases according to the coupling operation of the capacitor C.

As the first input signal IN1 of the first input node ND1 gradually increases, the fourth PMOS transistor MP4 turns off and the fourth NMOS transistor MN4 turns on, so the first output signal OUT1 of the first output node ND2 of the first inverter 210 decreases to the ground voltage GND.

The first output signal OUT1, i.e., the ground voltage GND, is transmitted to the second input node ND3 of the second inverter 220 through the turned-on second switch SW2.

As the voltage of the second input node ND3 decreases to the ground voltage GND, the PMOS transistors MP3 and MP5 turn on and the NMOS transistors MN3 and MN5 turn off

Therefore, the second output signal OUT2 of the second output node ND5 is pulled up from the ground voltage GND to the operating voltage VDD.

The exclusive OR circuit 610 generates an output signal having a first level L according to a second output signal OUT2 having data ‘0’ and a second level H, and the NAND circuit 620 generates a signal having a second level H according to the output signal of the exclusive OR circuit 610 having the first level L and an inverted read enable signal REB having the second level H, and outputs the signal to the clock terminal CLK of the D flip-flop 630. Therefore, the D flip-flop 630 generates a write termination signal WD having a second level H in response to the NAND circuit 620 transitioning to the second level H, and outputs the signal to the write driver 700.

The write driver 700 terminates the operation of writing data ‘1’ to the memory cell 400 in response to the write termination signal WD having the second level H, so that the second write current WI1 supplied to the source line SL is cut off. Accordingly, the voltage SLV of the source line SL drops to the ground voltage GND.

As the second input signal IN2 having a ground voltage GND is supplied to the first input node ND1 of the first inverter 210 through the turned-on bit line switch BLSW and the capacitor C, the first inverter 210 outputs a first output signal OUT1 having a second level H, and the second inverter 220 outputs a second output signal OUT2 having a first level L.

As illustrated in FIG. 8, when MTJ switching occurs in MTJ 410, the second output signal OUT2 generates a pulse waveform.

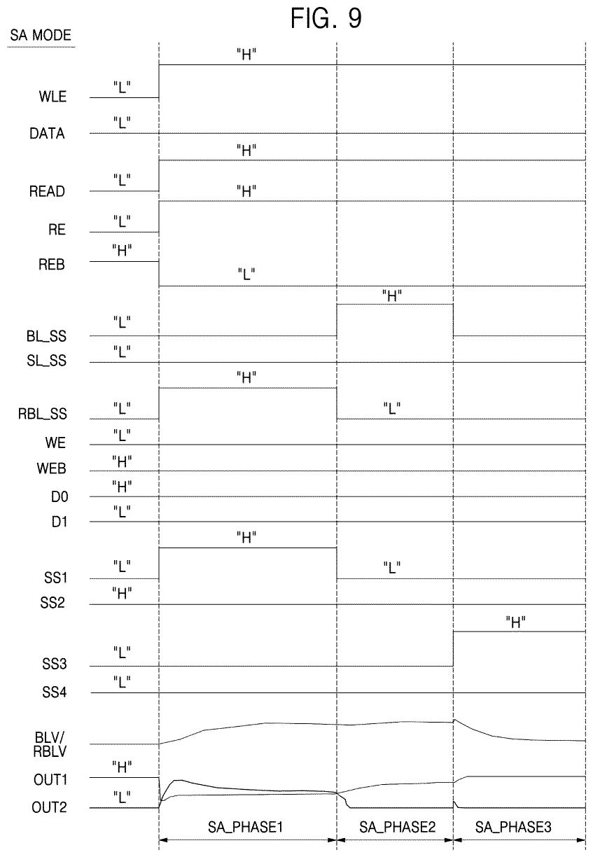

FIG. 9 is a timing diagram for explaining the sense amplifier mode performed by the dual mode inverter-based write termination circuit of FIG. 1.

The sense amplifier mode SA includes a first phase SA_PHASE1, a second phase SA_PHASW2, and a third phase (SA_PHASW3).

The first phase SA_PHASE1 of the sense amplifier mode SA is an offset removal phase, the second phase SA_PHASE2 of the sense amplifier mode SA is a pre-amplification phase, and the third phase SA_PHASE3 of the sense amplifier mode SA is a latch phase.

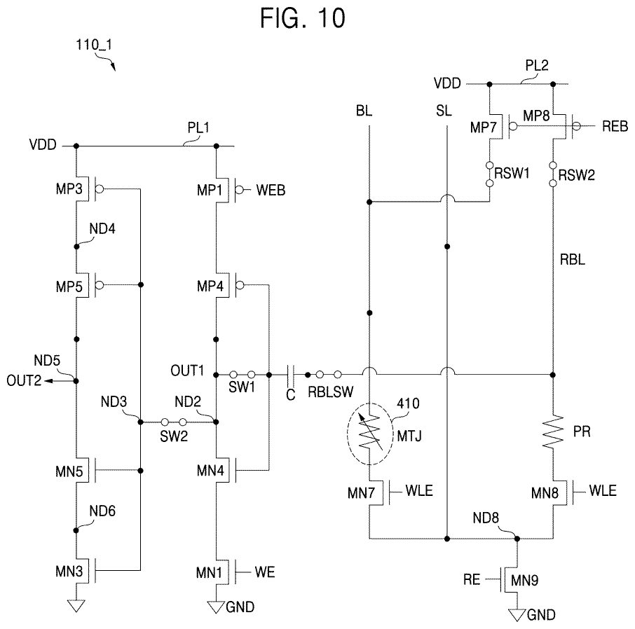

FIG. 10 is a circuit diagram of each of a write termination control circuit and a sense amplifier combined circuit, a switch circuit, a memory cell, and a reference memory cell for explaining the first phase of the sense amplifier mode. The DMI-WT circuit 110-1 of FIG. 10 is a conceptual diagram for explaining the first phase SA_PHASE1 of the sense amplifier mode SA.

In the sense amplifier mode SA, both the write termination signal generation circuit 600 and the write driver 700 are disabled.

Referring to FIGS. 4, 6, 9, and 10, in the first phase SA_PHASE1 of the sense amplifier mode SA, each of the word line enable signal WLE, the operation mode control signal READ instructing the sense amplifier mode SA, the read enable signal RE, the reference bit line switch signal RBL_SS, the first switch signal SS1, the second switch signal SS2, and the first control signal DO is at the second level H.

Additionally, each of the inverted read enable signal REB, the bit line switch signal BL_SS, the source line switch signal SL_SS, the third switch signal SS3, the fourth switch signal SS4, and the write enable signal WE is at the first level L.

As the first switch SW1 is turned on, the offset between the first input signal IN1 of the first input node ND1 of the first inverter 210 and the first output signal OUT1 of the first output node ND1 is removed.

The operating voltage VDD transmitted through the second voltage supply line PL2 is supplied to the bit line BL through the turned-on seventh PMOS transistor MP7 and the turned-on first reference cell switch RSW1, so that the voltage BLV of the bit line BL gradually increases (develops).

Additionally, the operating voltage VDD is supplied to the reference bit line RBL through the turned-on eighth PMOS transistor MP8 and the turned-on second reference cell switch RSW2, so that the voltage RBLV of the reference bit line RBL gradually increases.

As the voltage RBLV of the reference bit line RBL gradually increases, charges corresponding to the reference voltage are stored in the capacitor C.

As illustrated in FIG. 9, as the voltage of the first output node ND2 gradually increases, the second output signal OUT2 of the second output node ND5 gradually decreases.

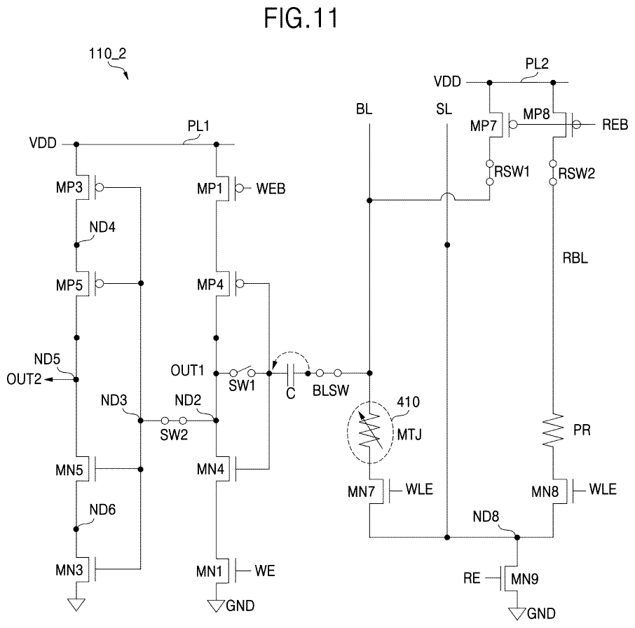

FIG. 11 is a circuit diagram of each of a write termination control circuit and a sense amplifier combined circuit, a switch circuit, a memory cell, and a reference memory cell for explaining the second phase of the sense amplifier mode.

Referring to FIGS. 9 and 11, in the second phase SA_PHASE2 of the sense amplifier mode SA, the first switch SW1 is turned off, the second switch SW2 remains on, the reference bit line switch RBL SW is turned off, and the bit line switch BLSW is turned on.

Here, the first inverter 210 pre-amplifies the signal received in the first phase SA_PHASE1. As the first output signal OUT1 of the first output node ND2 is pre-amplified and increases, the NMOS transistors MN3 and MN5 are turned on, and the second output voltage OUT2 of the second output node ND5 decreases to the ground voltage GND.

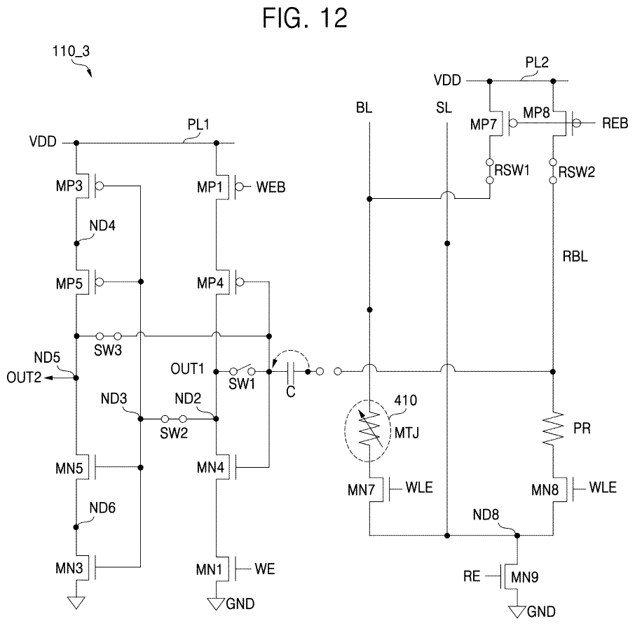

FIG. 12 is a circuit diagram of each of a write termination control circuit and a sense amplifier combined circuit, a switch circuit, a memory cell, and a reference memory cell for explaining the third phase of the sense amplifier mode.

In the third phase SA_PHASE3 of the sense amplifier mode SA, the first switch SW1 remains in an off state, the second switch SW2 remains in an on state, the third switch SW2 is turned on, the bit line switch BLSW is turned off, and the source line switch SLSW and the reference bit line switch RBLSW each remain in an off state.

The first output signal OUT1 of the first output node ND2 gradually increases to the operating voltage VDD, and the second output signal OUT2 maintains the ground voltage GND. As illustrated in FIGS. 9 and 10, data ‘0’ stored in the memory cell 400 is sensed, amplified, and detected by the DMI-WT circuit 110 used as a sense amplifier.

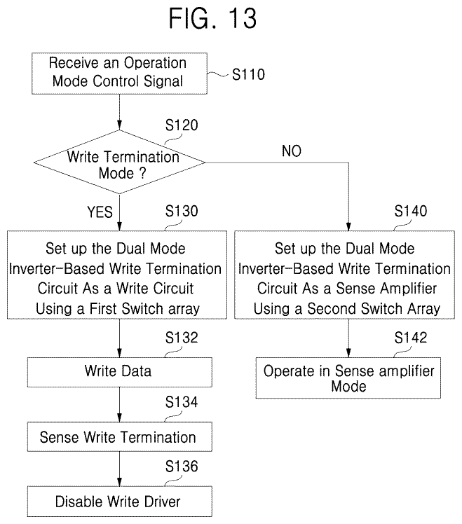

FIG. 13 is a flowchart for explaining the operation method of the memory device of FIG. 1. Referring to FIGS. 1 to 13, a dual mode inverter-based write termination circuit 110 used as both a write termination control circuit and a sense amplifier receives an operation mode control signal READ (S110), and can be used as either the write termination control circuit or the sense amplifier depending on the level of the operation mode control signal READ (e.g., whether it is a first level or a second level) (S120).

When the operation mode control signal READ is at the first level L, in order for the dual mode inverter-based write termination circuit 100 to be used as a write termination control circuit, the dual mode inverter-based write termination circuit (110) used as the write termination control circuit arranges the switches SW1 to SW5 in a first switch array as shown in FIG. 3 using switch control signals SS1 to SS5 (S130).

When the operation mode control signal READ is at the first level L and the data DATA is data ‘0’, the dual mode inverter-based write termination circuit 110 used as the write termination control circuit uses the first switch array and the write driver 700 to write data ‘0’ to the memory cell 400 (S132), detects that the data ‘0’ has been written to the memory cell 400 (S134), and generates a write termination signal WT having a second level H to terminate the operation of the write driver 700 (also referred to as ‘disable’) according to the detection result and outputs the signal to the write driver 700 (S136), as described with reference to FIG. 7.

When the operation mode control signal READ is at the first level L and the data DATA is data ‘1’, the dual mode inverter-based write termination circuit 110 used as the write termination control circuit uses the first switch array and the write driver 700 to write data ‘1’ to the memory cell 400 (S132), detects that the data ‘1’ has been written to the memory cell 400 (S134), and generates a write termination signal WT having a second level H to terminate the operation of the write driver 700 according to the detection result and outputs the signal to the write driver 700 (S136), as described with reference to FIG. 8.

However, when the operation mode control signal READ is at the second level H, in order for the dual mode inverter-based write termination circuit 100 to be used as a sense amplifier, the dual mode inverter-based write termination circuit 110 used as the sense amplifier arranges the switches SW1 to SW5 into a second switch array as shown in FIG. 4 using the switch control signals SS1 to SS5 (S140).

The dual mode inverter-based write termination circuit 110 used as a sense amplifier sequentially receives an output signal RBLV of the reference memory cell 500 and an output signal BLV of a memory cell 400 through one first input node ND1 to sense and amplify data (e.g., data ‘0’) stored in the memory cell 400 (S142).

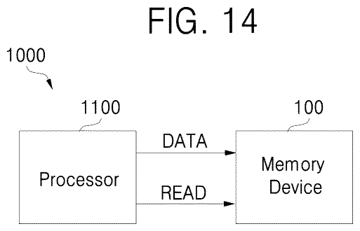

FIG. 14 is a block diagram of a memory system including the memory device of FIG. 1.

Referring to FIGS. 1 to 14, the memory system 1000 includes a processor (or control circuit) 1100 that generates data DATA and an operation mode control signal READ and a memory device 100.

The memory system 1000 may be an electronic device or a system on a chip, and the processor 1100 may utilize artificial intelligence.

While the present disclosure has been described with reference to the embodiments illustrated in the drawings, these are merely exemplary, and those of ordinary skill in the art to which the art pertains will appreciate that various modifications and other equivalent embodiments are possible from this. Therefore, the true technical protection scope of the present invention should be determined by the technical spirit set forth in the appended scope of claims.

What is claimed is:

1. A dual mode inverter-based write termination circuit comprising:
a first inverter including a first input node configured to receive a first input signal and a first output node configured to output a first output signal;
a second inverter including a second input node and a second output node;
a second switch connected between the first output node and the second input node;
a pull-up circuit configured to pull up the second input node to a first voltage in response to a first control signal;
a pull-down circuit configured to pull down the second input node to a second voltage in response to a second control signal; and
a voltage maintenance circuit configured to maintain a second output signal of the second output node.

2. The dual mode inverter-based write termination circuit of claim 1,
wherein the dual mode inverter-based write termination circuit further comprises:
an exclusive OR circuit configured to perform an exclusive OR operation on the second output signal and data;
a NAND circuit configured to perform a NAND operation on an output signal of the exclusive OR circuit and an inverted read enable signal;
a D flip-flop including a clock terminal configured to receive an output signal of the NAND circuit, an input terminal configured to receive the first voltage, and an output terminal configured to output a write termination signal; and
a write driver configured to perform either a write operation or a write termination operation on a Spin-Transfer Torque Magnetic Random-Access Memory in response to the write termination signal.

3. The dual mode inverter-based write termination circuit of claim 1,
wherein the first inverter comprises:
a first group of stacked PMOS transistors connected between a voltage transmission line configured to transmit the first voltage and the first output node;
a first group of stacked NMOS transistors connected between the first output node and ground configured to transmit the second voltage; and
a first switch connected between the first input node and the first output node.

4. The dual mode inverter-based write termination circuit of claim 3,
wherein the second inverter comprises:
a second group of PMOS transistors connected in series between the voltage transmission line and the second output node;
a second group of NMOS transistors connected in series between the second output node and the ground; and
a third switch connected between the first input node and the second output node,
wherein the gate of each of the second group of PMOS transistors and the gate of each of the second group of NMOS transistors are connected to the second input node.

5. The dual mode inverter-based write termination circuit of claim 4,
wherein the voltage maintenance circuit comprises:
a PMOS transistor and a fourth switch connected in series between the first common node of the second group of PMOS transistors and the ground; and
an NMOS transistor and a fifth switch connected in series between the second common node of the second group of NMOS transistors and the voltage transmission line, and the dual mode inverter-based write termination circuit,
wherein the gates of each of the PMOS transistor and the NMOS transistor are connected to the second output node.

6. The dual mode inverter-based write termination circuit according to claim 5,
wherein the dual mode inverter-based write termination circuit is used as both a write termination control circuit and a sense amplifier, and
when the dual mode inverter-based write termination circuit is used as the write termination control circuit, the third switch is always in an off state, the fourth switch and the fifth switch are always in an on state, and
when the dual mode inverter-based write termination circuit is used as the sense amplifier, the fourth switch and the fifth switch are always in an off state.

7. The dual mode inverter-based write termination circuit of claim 6,
wherein the dual mode inverter-based write termination circuit further comprises:
an exclusive OR circuit configured to perform an exclusive OR operation on the second output signal and data;
a NAND circuit configured to perform a NAND operation on an output signal of the exclusive OR circuit and an inverted read enable signal;
a D flip-flop including a clock terminal configured to receive an output signal of the NAND circuit, an input terminal configured to receive the first voltage, and an output terminal configured to output a write termination signal; and
a write driver configured to perform either a write operation or a write termination operation on a Spin-Transfer Torque Magnetic Random-Access Memory in response to the write termination signal.

8. A memory device comprising:
a memory cell;
a reference memory cell; and
a dual mode inverter-based write termination circuit including a write driver configured to write data to the memory cell,
wherein the dual mode inverter-based write termination circuit is configured to detect completion of writing data to the memory cell and terminate the operation of the write driver, and also sequentially receive an output signal of the reference memory cell and an output signal of the memory cell through one first input node to sense and amplify the data stored in the memory cell.

9. The memory device of claim 8,
wherein the dual mode inverter-based write termination circuit further comprises:
an exclusive OR circuit configured to perform an exclusive OR operation on the data and a second output signal output from the dual mode inverter-based write termination circuit;
a NAND circuit configured to perform a NAND operation on an output signal of the exclusive OR circuit and an inverted read enable signal; and
a D flip-flop including a clock terminal configured to receive an output signal of the NAND circuit, an input terminal configured to receive a first voltage, and an output terminal configured to output a write termination signal, and
wherein the write driver is configured to write the data to the memory cell in response to the write termination signal having a first level, and
is disabled in response to the write termination signal having a second level.

10. The memory device of claim 8,
wherein the dual mode inverter-based write termination circuit comprises:
a first inverter including the first input node and a first output node configured to output a first output signal; and
a first switch connected between the first input node and the first output node.

11. The memory device of claim 10,
wherein the first inverter comprises:
stacked PMOS transistors connected between a voltage transmission line configured to transmit a first voltage and the first output node; and
stacked NMOS transistors connected between the first output node and ground configured to transmit a second voltage, and
wherein a gate of one of the PMOS transistors and a gate of one of the NMOS transistors are connected to the first input node.

12. The memory device of claim 10,
wherein the dual mode inverter-based write termination circuit further comprises:
a second inverter including a second input node and a second output node;
a second switch connected between the first output node and the second input node;
a pull-up circuit configured to pull up the second input node to a first voltage in response to a first control signal;
a pull-down circuit configured to pull down the second input node to a second voltage in response to a second control signal; and
a voltage maintenance circuit configured to maintain a second output signal of the second output node.

13. The memory device of claim 12,
wherein the second inverter comprises:
PMOS transistors connected in series between a voltage transmission line configured to transmit the first voltage and the second output node;
NMOS transistors connected in series between the second output node and a ground configured to transmit the second voltage; and
a third switch connected between the first input node and the second output node, and
wherein the gates of each of the PMOS transistors and the gates of each of the NMOS transistors are connected to the second input node.

14. The memory device of claim 13,
wherein the voltage maintenance circuit comprises:
a PMOS transistor and a fourth switch connected in series between a first common node of the PMOS transistors and the ground; and
an NMOS transistor and a fifth switch connected in series between a second common node of the NMOS transistors and the voltage transmission line,
wherein the gates of each of the PMOS transistor and the NMOS transistor are connected to the second output node.

15. A memory system comprising:
a processor configured to output data; and
a memory device configured to receive the data,
the memory device comprising:
a memory cell;
a reference memory cell; and
a dual mode inverter-based write termination circuit including a write driver configured to write data to the memory cell,
wherein the dual mode inverter-based write termination circuit is configured to detect completion of writing data to the memory cell and terminate an operation of the write driver, and also sequentially receive an output signal of the reference memory cell and an output signal of the memory cell through one first input node to sense and amplify the data stored in the memory cell.

16. The memory system of claim 15,
wherein the dual mode inverter-based write termination circuit comprises:
a first inverter including the first input node and a first output node configured to output a first output signal;
a second inverter including a second input node and a second output node;
a second switch connected between the first output node and the second input node;
a pull-up circuit configured to pull up the second input node to a first voltage in response to a first control signal;
a pull-down circuit configured to pull down the second input node to a second voltage in response to a second control signal; and
a voltage maintenance circuit configured to maintain a second output signal of the second output node.

17. The memory system of claim 16,
wherein the first inverter comprises:
a first group of stacked PMOS transistors connected between a voltage transmission line configured to transmit the first voltage and the first output node;
a first group of stacked NMOS transistors connected between the first output node and ground transmitting the second voltage; and
a first switch connected between the first input node and the first output node.

18. The memory system of claim 15,
wherein the dual mode inverter-based write termination circuit comprises:
an exclusive OR circuit configured to perform an exclusive OR operation on the data and an output signal of the dual mode inverter-based write termination circuit;
a NAND circuit configured to perform a NAND operation on an output signal of the exclusive OR circuit and an inverted read enable signal; and
a flip-flop comprising a clock terminal configured to receive an output signal of the NAND circuit, an input terminal configured to receive the first voltage, and an output terminal configured to output a write termination signal, and
wherein the write driver is configured to write the data to the memory cell or disable depending on the level of the write termination signal.
